(19) United States
(12) Patent Application Publication
(10) Pub. No.: US 2019/0086494 A1
(43) Pub. Date: Mar. 21, 2019

(54) MAGNETIC RESONANCE FINGERPRINTING METHOD AND APPARATUS

(71) Applicant: Siemens Healthcare GmbH, Erlangen (DE)

(72) Inventor: Josef Pfeuffer, Kunreuth (DE)

(73) Assignee: Siemens Healthcare GmbH, Erlangen (DE)

(21) Appl. No.: 16/135,257

(22) Filed: Sep. 19, 2018

(30) Foreign Application Priority Data
Sep. 19, 2017 (EP) 17191849

(51) Int. Cl. G01R 33/48; G01R 33/54; G01R 33/36; G01R 33/385

(52) U.S. Cl. CPC G01R 33/4818; G01R 33/385; G01R 33/3607; G01R 33/543

(57) ABSTRACT

In a method and apparatus for magnetic resonance (MR) fingerprinting, parameters that describe a starting k-space trajectory, along which measurement data are to be acquired in an MR fingerprinting sequence, are loaded into a computer, and at least one measurement k-space trajectory is created in the computer by fluctuating one of the parameters of the starting k-space trajectory. Measurement data are recorded along the measurement k-space trajectory, and the MR fingerprinting sequence is repeated with a different measurement trajectory in each repetition, produced by fluctuation of the at least one parameter of the starting k-space trajectory.

### BACKGROUND OF THE INVENTION

### Field of the Invention

The present invention concerns magnetic resonance fingerprinting.

### Description of the Prior Art

Magnetic resonance (MR) technology is a known technology with which images of the interior of an examination object can be generated. In simple terms, the examination object is positioned in a magnetic resonance scanner in a strong static, homogenous basic magnetic field, also referred to as a B₀ field, with field strengths of 0.2 tesla to 7 tesla or more, such that nuclear spins in the object orient themselves along the basic magnetic field. To trigger magnetic resonance signals, radio-frequency excitation pulses (RF pulses) are radiated into the examination object, with rapidly switched magnetic gradient fields being superimposed on the basic magnetic field for spatially encoding the triggered MR signals. The recorded signals are digitized and stored as complex numerical values in a memory as so-called k-space data, such as in a matrix. An associated MR image can be reconstructed from k-space matrix populated with values, for example, by means of a multidimensional Fourier transformation. Spectroscopy data can alternatively be required.

Magnetic resonance imaging can serve to determine the presence and/or distribution of a substance in the examination object. The substance can be, for example, a suspected pathological tissue of the examination object, a contrast agent, a tracer substance, or a metabolite.

Information about the substances that are present can be obtained from the recorded measurement data in many ways. Image data reconstructed from the measurement data, for example, are a relatively simple source of information. However, there are also more complex methods that, for example, determine information about the examination object from a pixel time series in the image data reconstructed from successively measured measurement datasets.

Such methods include, for example, magnetic resonance fingerprinting methods (MRF methods) in which signal waveforms of image data reconstructed from measurement data recorded chronologically using different recording parameters (“fingerprinting parameters”) are compared by pattern recognition with signal waveforms of a previously determined database of signal waveforms that are known to be characteristic of specific substances (“dictionary”). The substances represented in the image data reconstructed from the measurement data and/or the spatial distribution of tissue-specific parameters (such as transverse relaxation T2 or longitudinal relaxation T1; so-called T1 and T2 maps) in the imaged examination object can thus be determined.

Magnetic resonance fingerprinting methods are known, for example, in the article by Ma et al., “Magnetic Resonance Fingerprinting”, Nature, 495: p. 187-192 (2013), the article by Jiang et al., “MR Fingerprinting Using Fast Imaging with Steady State Precession (FISP) with Spiral Readout”, Magnetic Resonance in Medicine 74: p. 1621-1631 (2015) or the article by Cloos et al. “Online Radial Multiband Magnetic Resonance Fingerprinting”, ISMRM 2016: p. 608.

In the aforementioned article by Jiang et al., an MRF method is described in which an FISP (“Fast Imaging with Steady State Precession”) sequence is used which is repeated 1000 times with variation of the repetition time TR and the flip angle, wherein measurement data are recorded along a spiral k-space trajectory with each repetition. In the method described, 24 repetitions are required to completely scan k-space center with k-space trajectory so as to satisfy the Nyquist criterion, and 48 repetitions to achieve an overall resolution of 256*256 in which the peripheral k-space region is also completely scanned so as to fulfill the Nyquist criterion. K-space trajectory that is used is therefore rotated by an angle increment of 360°/48=7.5° in every repetition. A measurement dataset of a repetition from which image data are reconstructed is therefore undersampled 48 times. Therefore, the reconstructed image data from which the pixel time series for comparison with the database is created displays severe undersampling artifacts (cf. Figure 6d or 7a in Jiang et al.). Although in the article Jiang et al. conclude that these undersampling artifacts average each other out overall, and therefore have no influence on the parameter maps that are obtained as results of the comparison with the database, spatially erroneous deviations/displacements (“spatial bias”), which are also referred to as shading artifacts, may still occur in the parameter maps (cf. Figure 7b in Jiang et al.).

In the article by Pfeuffer et al. “Mitigation of Spiral Undersampling Artifacts in Magnetic Resonance Fingerprinting (MRF) by Adapted Interleave Reordering”, Proc. Int. Soc. Magn. Reson. Med., 2017, 133, and in the subsequently published EP17185874, a method is described in which the sequence of k-space trajectories, along which measurement data is recorded in successive repetitions, is optimized to avoid or reduce disturbing artifacts in image data reconstructed from the measurement data of a repetition. By optimizing the sequence in which k-space trajectories are scanned, a temporal averaging effect is achieved that already reduces the unwanted artifacts. Optimization is cumbersome, however, because further effects such as the respective design of k-space trajectory, the sampling density, as well as MRF-specific parameters (selected flip angles, repetition times, . . . ) can play a role.

### SUMMARY OF THE INVENTION

An object of the invention is to avoid artifacts in datasets obtained by MRF methods.

A method according to the invention for generating measurement data of an examination object by means of magnetic resonance fingerprinting has the following steps.

Parameters that describe a starting k-space trajectory along which measurement data are to be recorded are loaded into a computer. At least one measurement k-space trajectory is created in the computer by fluctuation of at least one of the parameters that determines the course of the starting k-space trajectory. The computer then generates a measurement protocol that includes the created measurement k-space trajectory, and then generates control signals corresponding to the measurement protocol. The computer provides the control signals to an MR scanner so as to operate the MR scanner in order to record measurement data along the measurement k-space trajectory. The recording of measurement data is repeated along measurement k-space trajectories respectively in the individual repetitions that were created using different fingerprinting parameters, until all the desired measurement data have been recorded. The recorded measurement data are stored in a memory as a measurement dataset.

The invention is based on the insight that additional signals are always superimposed on an MRF target signal of a pixel, i.e. the result of comparison with characteristic signal waveforms, and the pixel is therefore afflicted by noise. In each case, the additional signals originate from all the other pixels of the recorded image, and these additional signals are not random, but are coherent and change with every repetition of the sampling of a k-space trajectory depending on the respective k-space trajectory (e.g. depending on the respective angle of rotation). These coherences result in systematic errors and distorted MRF results, which manifest themselves as artifacts, sometimes referred to as foldover artifacts.

The fluctuation of at least one parameter determining the course of the starting k-space trajectory in k-space ensures that the measurement k-space trajectory that is created does not follow a stringent path, as is conventional, even in k-space, but is erratic, although in a controlled manner. The recording of measurement data along such wavering (swaying) measurement k-space trajectories produces incoherent noise in the recorded signals, and thus avoids the aforementioned systematic errors, distortions and artifacts in results obtained by MRF, such as maps of decay constants.

The fluctuation of at least one parameter of a group of parameters that determine the course of k-space trajectory can be implemented by random variation of the respective parameter, within predetermined limit values. The random variation ensures a sufficiently erratic course. The specification of limit values within which the parameters should lie despite the fluctuation, affords better control including, for example, evaluating the feasibility of the measurement k-space trajectories obtained.

The amplitudes of the gradients used, the slew rates of the gradients used, and, if applicable, parameters dependent hereon such as the starting position of a starting k-space trajectory or starting angle for radial or spiral starting k-space trajectories or the course of the radius of a spiral starting k-space trajectory, are taken into consideration as parameters of this group, particularly in the course of time in each case.

Fluctuation occurs advantageously such that a spatial and/or temporal distribution of the noise contained in the recorded signals is as homogenous as possible.

To this end, for example, framework conditions (e.g. limit values during fluctuation) for the fluctuation of the parameters to be fluctuated can be selected optimized in such a way that a desired homogeneity of the spatial and/or temporal distribution of the noise contained in the recorded signals is achieved, whereby undersampling artifacts in image data reconstructed from the measurement data are reduced. A measurement period necessary for an obtained measurement k-space trajectory and/or also hardware restrictions, for example, may be further criteria in the optimized selection of framework conditions. For example, large variations in the amplitude of a gradient to be switched (activated) for a measurement k-space trajectory caused by fluctuation may result in the measurement period being extended, but this is acceptable because a certain amount of variation in the parameter is desirable. It may therefore be expedient to specify or determine minimum and/or maximum values for the fluctuation of the parameters such that image data with as few artifacts as possible can be reconstructed from the measurement data recorded along the measurement k-space trajectories. In the process, various criteria may be taken into account. For example, an only modest fluctuation of the parameter to be fluctuated, and thus a small spatial redistribution of noise contained in the recorded measurement data, can already lead to satisfactory results if the temporal distribution of the noise is sufficiently non-uniform, for example, as a result of different fluctuations in different repetitions.

A magnetic resonance apparatus according to the invention has an MR data acquisition scanner that has a basic field magnet, a gradient system, a radio-frequency (RF) system and a control computer designed to implement the method according to the invention by controlling the operation of an RF transmit/receive controller of the RF system, and a fluctuation unit.

The present invention also encompass a non-transitory, computer-readable data storage medium encoded with programming instructions that, when the storage medium is loaded into a computer or computer or computer system of a magnetic resonance apparatus, cause the computer or computer system to operate the magnetic resonance apparatus in order to implement any or all embodiments of the method according to the invention, as described above.

The advantages and embodiments described with regard to the method apply analogously to the magnetic resonance apparatus and the electronically readable data carrier.

### BRIEF DESCRIPTION OF THE DRAWINGS

FIG. 1 is shows a flowchart of the method according to the invention.

FIG. 2 shows an example of the chronological sequence of a parameter determining the course of a k-space trajectory.

FIG. 3 shows another example of the chronological sequence of a parameter determining the course of a k-space trajectory.

FIG. 4 shows an example of the result of a fluctuation of the parameter from FIG. 2.

FIG. 5 shows an example of the result of a fluctuation of the parameter from FIG. 3.

FIG. 6 shows an example of the course of starting k-space trajectories in k-space.

FIG. 7 shows exemplary measurement k-space trajectories proceeding from the starting k-space trajectories shown in FIG. 6.

FIG. 8 is a schematic illustration of a magnetic resonance system according to the invention.

### DESCRIPTION OF THE PREFERRED EMBODIMENTS

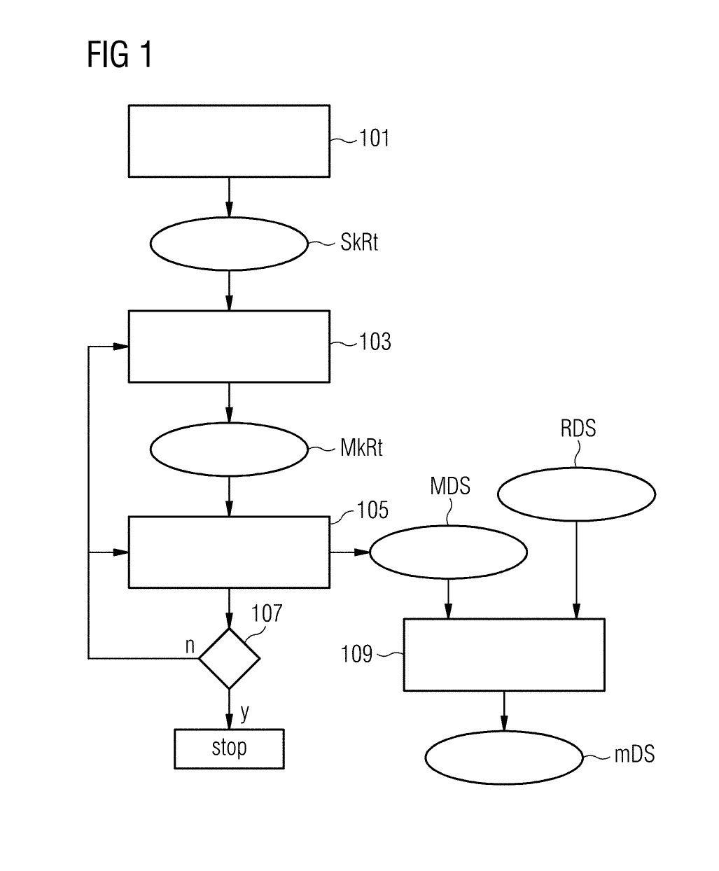

FIG. 1 is a flowchart of the method according to the invention for generating measurement data of an examination object by magnetic resonance fingerprinting.

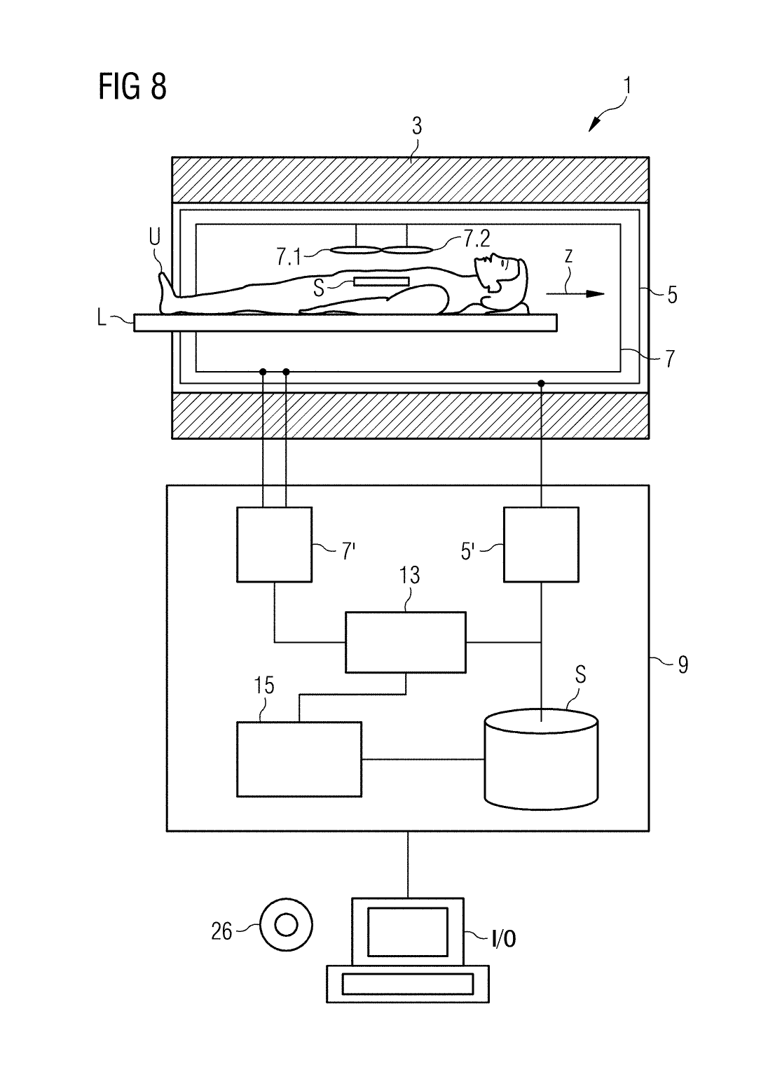

In the method, parameters are loaded into the control computer 9 of an MR apparatus 1 (shown in FIG. 8). The parameters describe a starting k-space trajectory SkRt, along which generated MR echo signals are to be entered into k-space as measurement data MDS (block 101). The loaded parameters contain information about RF pulses to be radiated, gradients to be switched, and readout times in their chronological order and relation to one another.

The starting k-space trajectory described by way of the parameters can be a Cartesian k-space trajectory or a radial or spiral k-space trajectory.

It is possible to record all the desired measurement data along only one k-space trajectory after only one excitation of echo signals (so-called “single-shot” method). Frequently the recording of measurement data takes place in a segmented manner, however, i.e. k-space is scanned (filled with acquired signals) in several steps (so-called “multi-shot” method) along respective k-space trajectories that change from step-to-step (repetition-to-repetition). With such segmented recording, a starting k-space trajectory SkRt can be specified for each segment. It is also possible to determine one starting k-space trajectory SkRt for a respective segment, for example, by rotation and/or translation in k-space, starting from a common starting k-space trajectory SkRt.

Parameters for at least two starting k-space trajectories SkRt can be loaded in block 101 for segmented recordings of MR measurement data, namely, parameters for one starting k-space trajectory SkRt per planned segment.

If at least two starting k-space trajectories SkRt are loaded for which measurement k-space trajectories MkRt are to be created, along which measurement data are to be recorded, a single starting k-space trajectory SkRt can be selected such that, by itself, k-space is not sampled according to the Nyquist criterion. The loaded starting k-space trajectories can be selected such that together they scan k-space with the desired degree of completeness. If, for example, (further) overall incomplete scanning by the loaded starting k-space trajectories SkRt is selected to reduce the measurement duration, appropriate supplementary methods such as Partial Fourier methods, parallel acquisition methods or iterative reconstruction methods can then be used for the reconstruction of image data from the measurement data MDS. This may also be the case for single-shot methods.

For each starting k-space trajectory SkRt loaded according to the loaded parameters, at least one measurement k-space trajectory MkRt is created by fluctuating at least one parameter that determines the course of the starting k-space trajectory (block 103).

As a result of fluctuation, the course of the measurement k-space trajectory MkRt for successive measurement points deviates in each case from the course of the associated starting k-space trajectory SkRt in a different manner. Thus, not only the location or position of the measurement k-space trajectory MkRt changes as a result of fluctuation compared to the associated starting k-space trajectory SkRt, but also the shape is altered such that the measurement k-space trajectory MkRt in k-space no longer follows a stringent path like the original starting k-space trajectory SkRt, but deviates erratically from the original starting k-space trajectory SkRt.

Fluctuation can be implemented by random variation of at least one parameter that determines the course of k-space trajectory, within predefined limit values.

In this case, the fluctuation can continue to occur in order to make a spatial and/or temporal distribution of the noise contained in the recorded signals is as homogenous as possible. To this end, for example, boundary conditions can be specified for the fluctuation which ensure that the respective measurement k-space trajectories MkRt are fluctuated and/or chronologically distributed in successive recordings of measurement data such that noise contained in the recordings is as incoherent as possible.

Such boundary conditions can also strike a balance, for example, between the extremes of maximum incoherence (and thus minimum artifacts), and maximum quality of the MRF parameter maps obtained or MR images produced from the measurement data or a minimum measurement period and/or acquisition length. The boundary conditions can be optimized so as to strike this balance in a desired manner. Optimization criteria for this can be determined on the basis of MR (basic) images reconstructed from (undersampled) measurement data and/or MRF parameter maps that have been obtained.

At least one parameter that determines the course of k-space trajectory that is fluctuated can be, for example, the starting angle of the starting k-space trajectory for radial or spiral starting k-space trajectories, such that the measurement k-space trajectories also include “curved” starting angles that do not depend in a linear fashion on a number of existing starting k-space trajectories, and which would not be used as “intermediate angles” in conventional methods. In the case of spiral starting k-space trajectories, at least one parameter that determines the course of k-space trajectory and to be fluctuated can additionally or alternatively be the radius that is dependent on the amplitude of the switched gradients (in chronological sequence) of the starting k-space trajectory. In the case of Cartesian k-space trajectories at least one parameter that determines the course of k-space trajectory that is fluctuated can be a parameter of the switched gradients, such as their amplitude, which determines the position of a measurement point in k-space.

In repeated recordings of measurement data in the desired region of k-space, for example for MRF methods in which a multiplicity (up to several hundreds or even thousands) of repetitions of recordings are performed per scanned k-space trajectory for the creation of a fingerprint, different measurement k-space trajectories MkRt can be produced respectively for each repetition of a recording along a starting k-space trajectory SkRt.

Thus, measurement data MDS can be repeatedly recorded in at least two repetitions based on a starting k-space trajectory SkRt, wherein for each repetition of the recording of the measurement data MDS, in each case different measurement k-space trajectories MkRt are produced proceeding from the starting k-space trajectory SkRt. As a result of such a constant fluctuation of k-space trajectories along which the measurement data are repeatedly recorded, a particularly high degree of incoherence can be achieved in the noise contained in the measurement data.

It is also conceivable for precisely one measurement k-space trajectory to be produced in each case for each loaded starting k-space trajectory SkRt. A restriction of the fluctuation such that, for each starting k-space trajectory SkRt, only one measurement k-space trajectory MkRt is produced in each case, along which measurement data are recorded in each repetition of the MRF measurement, can be advantageous for an iterative reconstruction and/or data compressibility. As a result of such a restriction of fluctuation in the time domain, for example, better use may be made of an iterative reconstruction and/or a time domain compression in main components.

In each case, measurement data MDS are recorded along the created measurement k-space trajectories MkRt (block 105), and are stored in a measurement dataset.

If all the desired measurement data have already been recorded (query 107, “y”), measurement ends (“stop”). If not all the desired measurement data MDS has yet been recorded (query 107, “n”), the recording of measurement data MDS along created measurement k-space trajectories MkRt is repeated with different fingerprinting parameters. As described above, measurement k-space trajectories MkRt already created can be used, or, based on the loaded starting k-space trajectories SkRt, measurement k-space trajectories MkRt produced again by renewed fluctuation.

The measurement data MDS stored in the measurement dataset are compared with a reference dataset RDS, such as an MRF dictionary, to produce desired parameter maps mDS (block 109).

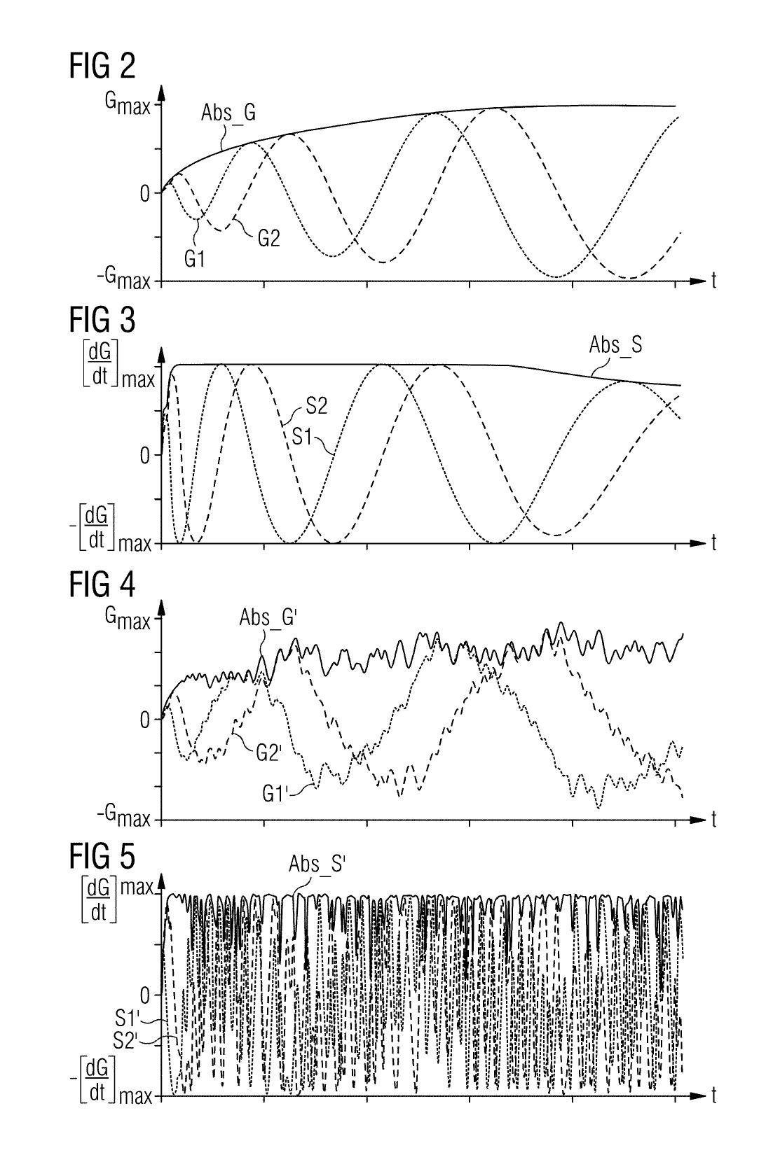

FIG. 2 shows an example of the chronological sequence of a parameter that determines the course of a k-space trajectory, here the amplitude of the switched gradients.

In the example shown, the change in the amplitude is shown over the time t of a first gradient to be switched G1, which is created in a first direction, e.g. in a read-out direction, and of a second gradient to be switched G2, which is created in a second direction, e.g. in a phase encoding direction, which differs from the first direction and is perpendicular to the first direction. Such a switching of gradients results in a typical two-dimensional (2D), stringent, spiral k-space trajectory, which can be used as a starting k-space trajectory. Furthermore, the absolute value Abs_G of both gradients G1 and G2 is plotted in FIG. 2.

In FIG. 3 the slew rates S1 and S2 pertaining to the gradients G1 and G2 and their absolute value Abs_S are shown, and thus a further example (albeit dependent on FIG. 2) of the chronological sequence of a parameter determining the course of a k-space trajectory. The slew rate of a gradient is obtained by derivation according to the time.

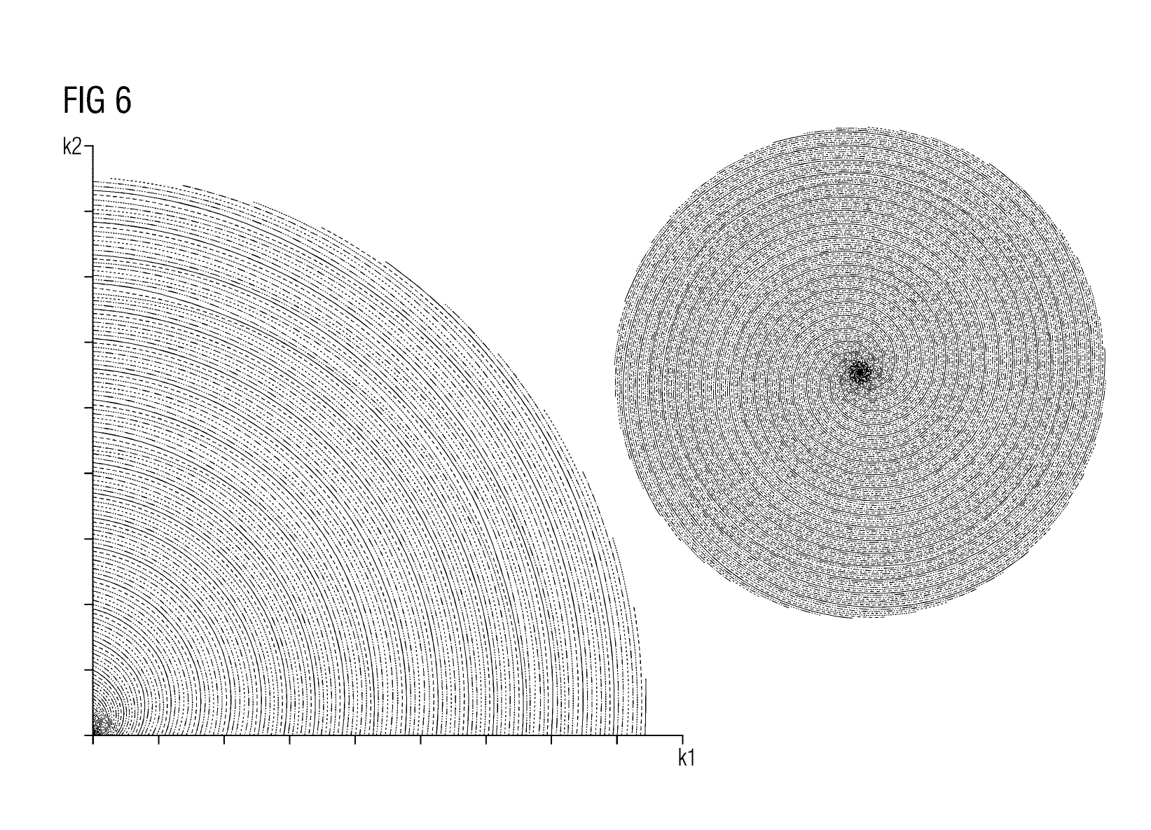

A representation of a number, here 48, of such (2D in k-space directions k1 and k2) spiral (starting) k-space trajectories which can each be converted into each other by means of rotation is shown in FIG. 6, wherein all k-space trajectories are shown on the right and, for better visibility, an enlarged section of a quadrant of the same k-space on the left. K-space trajectories of this sort, such as are also used in the aforementioned article by Jiang et al., can serve as starting k-space trajectories for the method described herein.

FIGS. 4, 5 and 7 show exemplary results of a fluctuation according to the invention.

FIG. 4 shows the result of a fluctuation of the amplitudes of the gradients G1 and G2 from FIG. 2. The gradient G1′, which winds around the course of the gradient G1, was determined from the gradient G1. The gradient G2′, which winds around the course of the gradient G2, was determined from the course of the gradient G2. The absolute value Abs_G′ of the two gradients G1′ and G2′ also fluctuates erratically around the course of the original absolute value Abs_G.

As shown in FIG. 5, as a result of fluctuation the slew rates S1′ and S2′ pertaining to the gradients G1′ and G2′ respectively, and their absolute value Abs_S are also highly erratic compared to the original course in FIG. 3. In the case of fluctuation, it may thus be expedient to take account of maximum possible slew rates and switching times as a framework condition.

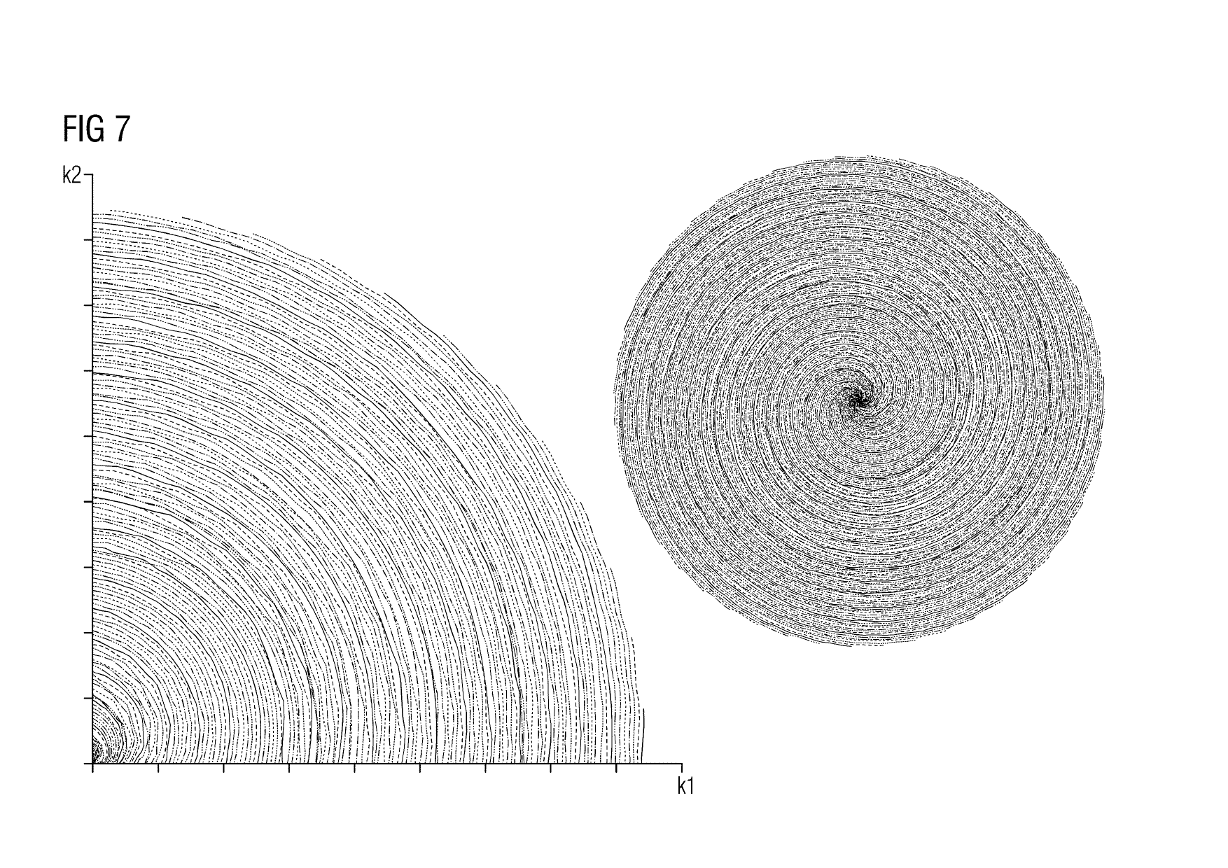

Corresponding to FIG. 6, in FIG. 7 representations of measurement k-space trajectories as have been created, for example, after fluctuation of parameters of the starting k-space trajectories from FIG. 6 are shown, on the left, in the overall view, and on the right, enlarged.

Each of the 48 starting k-space trajectories from FIG. 6 has been fluctuated in its own way so that k-space points on a measurement k-space trajectory at which measurement data was recorded successively are at locally varying distances and/or the depicted field of view varies. Furthermore, a different fluctuation of the respective starting k-space trajectories ensures that a noise contained in measurement data recorded along one of the measurement k-space trajectories is spatially distributed in a different manner in each case. This avoids or at least reduces systematic errors in signal waveforms determined from the recorded measurement data.

If the recording of measurement data along measurement k-space trajectories created on the exemplary 48 starting k-space trajectories is repeated with different fingerprinting parameters, furthermore the sequence in which the measurement k-space trajectories created on the basis of starting k-space trajectories are scanned in succession can be optimized such that a noise contained in the recorded measurement data is also temporally distributed as differently as possible. Thus, the fluctuation of the starting k-space trajectories may also include an optimization of the sequence of the measurement k-space trajectories to be scanned in succession.

A fluctuation of other types of starting k-space trajectories, for example, radial or Cartesian, can be implemented analogously.

FIG. 8 is a block diagram of a magnetic resonance apparatus 1 according to the invention. This includes an MR data acquisition scanner having a basic field magnet 3 that generates the basic magnetic field, a gradient coil arrangement 5 that generates the gradient fields, an RF antenna 7 for radiation and reception of radio-frequency signals, and a control computer 9 designed to perform the method according to the invention. In FIG. 8 these sub-units of the magnetic resonance apparatus 1 are shown only in a roughly schematic manner. The RF antenna 7 may be composed of several sub-units, for example, several coils such as the schematically shown coils 7.1 and 7.2 or more coils which may be designed either for only transmitting radio-frequency signals or only for receiving the triggered radio-frequency signals or, for both.

For the examination of an examination object U, for example a patient or a phantom, the object U can be introduced into the measuring volume of the scanner of the magnetic resonance apparatus 1 on a bed L. The slice S represents an exemplary target volume of the examination object from which measurement data are to be acquired.

The control computer 9 is configured to control the magnetic resonance apparatus 1 and, in particular, controls the gradient coil arrangement 5 via a gradient controller 5′ and the RF antenna 7 via an RF transmit/receive controller 7′. The RF antenna 7 may have several channels via which signals can be transmitted or received.

The RF antenna 7, together with its RF transmit/receive controller 7′, is responsible for the generation and radiation (transmission) of a radio-frequency alternating field for manipulating the spins in a region of the object U from which MR signals are to be acquired (for example, in slices S). In this case, the center frequency of the radio-frequency alternating field, also referred to as the B1 field, must be close to the resonance frequency of the spins to be manipulated. To generate the B1 field, currents controlled by the radio-frequency transmit/receive controller 7′ are applied to the RF coils in the RF antenna 7.

Furthermore, the control computer 9 has a fluctuation unit (circuit or processor) 15 with which k-space trajectories can be fluctuated and if necessary, optimized framework conditions for fluctuation can be established. Overall, the control computer 9 is designed to perform the method according to the invention for avoiding artifacts when acquiring MR data of the examination object U.

An arithmetic processor 13 of the control computer 9 is designed to perform all the computing operations necessary for the required measurements and determinations. Intermediate results and results required for this purpose or determined in this case can be stored in a storage unit S of the control computer 9. The units shown are not necessarily to be understood as physically separate units, but merely represent a subdivision into units of meaning which can also be realized, for example, in fewer or even in only one single physical unit.

Via an I/O (input/output) device of the magnetic resonance apparatus 1, control commands can be entered by an operator into the magnetic resonance apparatus 1 and/or results of the control computer 9, such as image data, displayed.

The method described herein may also be embodied as an electronically readable data carrier (storage medium) 26 with electronically readable control information (program code) stored thereon. When the data carrier 26 is loaded into the control computer 9 of the magnetic resonance apparatus 1, the program code cause the control computer 9 to operate the magnetic resonance apparatus 1 as described above.

Although modifications and changes may be suggested by those skilled in the art, it is the intention of the Applicant to embody within the patent warranted hereon all changes and modifications as reasonably and properly come within the scope of the Applicant's contribution to the art.

1. A method for generating measurement data if an examination object by magnetic resonance (MR) fingerprinting, said method comprising:
prior to operating an MR scanner in order to execute an MR fingerprinting sequence, in which measurement data will be acquired and entered into a memory organized as k-space along a measurement trajectory in k-space, loading parameters into a processor that describe a starting k-space trajectory along which said measurement data will be entered into k-space;
in said processor, generating said measurement k-space trajectory by fluctuating at least one of said parameters that determines said starting k-space trajectory;
from said processor, operating said MR scanner so as to execute said MR fingerprinting sequence with measurement data acquired in said MR fingerprinting sequence being entered into said memory along said measurement k-space trajectory;
from said processor, operating said MR scanner to repeat execution of said MR fingerprinting sequence in a plurality of repetitions with, in each repetition, a different measurement k-space trajectory being used by further fluctuation of said at least one of said parameters, with different MR fingerprinting parameters in the respective repetitions, until a repetition termination criterion is satisfied; and
from said processor, storing all of the measurement data acquired in all of said repetitions as a measurement data set in a measurement data set storage memory.

2. A method as claimed in claim 1 comprising fluctuating said parameter by random variation of said parameter, within predetermined limit values.

3. A method as claimed in claim 1 comprising fluctuating said parameter in order to make a noise distribution in said measurement data homogenous, said noise distribution being selected from the group consisting of a spatial noise distribution and a temporal noise distribution.

4. A method as claimed in claim 1 comprising loading parameters for at least two starting k-space trajectories into said processor, and creating only one measurement k-space trajectory from said two starting k-space trajectories.

5. A method as claimed in claim 1 comprising loading a k-space trajectory, as said starting k-space trajectory that undersamples k-space according to the Nyquist criterion.

6. A method as claimed in claim 1 comprising loading a k-space trajectory, as said starting k-space trajectory, selected from the group consisting of a radial k-space trajectory and a spiral k-space trajectory, and wherein said parameter that is fluctuated is a starting angle of said starting k-space trajectory.

7. A method as claimed in claim 1 comprising loading a k-space trajectory, as said starting k-space trajectory, selected from the group consisting of a radial k-space trajectory and a spiral k-space trajectory, and wherein said parameter that is fluctuated is a starting radius of said starting k-space trajectory.

8. A method as claimed in claim 1 comprising generating a parameter map from the stored measurement data, and comparing said measurement map to a database comprising characteristic waveforms in order to determine a signal waveform, among said measurement data, that most closely corresponds to a signal waveform in said database, in order to identify a substance of said examination object.

9. A magnetic resonance (MR) apparatus comprising:
an MR scanner;
a processor configured to receive, prior to operating an MR scanner in order to execute an MR fingerprinting sequence, in which measurement data will be acquired and entered into a memory organized as k-space along a measurement trajectory in k-space, parameters that describe a starting k-space trajectory along which said measurement data will be entered into k-space;
said processor being configured to generate said measurement k-space trajectory by fluctuating at least one of said parameters that determines said starting k-space trajectory;
said processor being configured to operate said MR scanner so as to execute said MR fingerprinting sequence with measurement data acquired in said MR fingerprinting sequence being entered into said memory along said measurement k-space trajectory;
said processor being configured to operate said MR scanner to repeat execution of said MR fingerprinting sequence in a plurality of repetitions with, in each repetition, a different measurement k-space trajectory being used by further fluctuation of said at least one of said parameters, with different MR fingerprinting parameters in the respective repetitions, until a repetition termination criterion is satisfied; and
said processor being configured to store all of the measurement data acquired in all of said repetitions as a measurement data set in a measurement data set storage memory.

10. A non-transitory, computer-readable data storage medium encoded with programming instructions, said storage medium being loaded into a computer of a magnetic resonance (MR) apparatus that comprises an MR scanner, and said programming instructions causing said computer system to:
prior to operating an MR scanner in order to execute an MR fingerprinting sequence, in which measurement data will be acquired and entered into a memory organized as k-space along a measurement trajectory in k-space, receive parameters that describe a starting k-space trajectory along which said measurement data will be entered into k-space;
generate said measurement k-space trajectory by fluctuating at least one of said parameters that determines said starting k-space trajectory;
operate said MR scanner so as to execute said MR fingerprinting sequence with measurement data acquired in said MR fingerprinting sequence being entered into said memory along said measurement k-space trajectory;
operate said MR scanner to repeat execution of said MR fingerprinting sequence in a plurality of repetitions with, in each repetition, a different measurement k-space trajectory being used by further fluctuation of said at least one of said parameters, with different MR fingerprinting parameters in the respective repetitions, until a repetition termination criterion is satisfied; and
store all of the measurement data acquired in all of said repetitions as a measurement data set in a measurement data set storage memory.
